(19) United States
(12) Patent Application Publication
(10) Pub. No.: US 2008/0308144 A1
(43) Pub. Date: Dec. 18, 2008

(54) Integrated thin-layer photovoltaic module

(75) Inventors: Elena M. Shembel, Coral Springs, FL (US); Aleksandr Skurtul, Kiev (UA); Aleksandra Shmyryeva, Kiev (UA); Tymofiy V. Pastushkin, Ft. Lauderdale, FL (US); Anatoliy Alpatov, Dnepropetrovsk (UA)

Correspondence Address: Elena Shembel, 4956 Rothschild Dr, Coral Springs, FL, 33067, US

(73) Assignee: Enerize Corporation, Coral Springs, FL (US)

(21) Appl. No.: 12/228,485

(22) Filed: Aug. 13, 2008

(30) Foreign Application Priority Data
Feb. 14, 2006 (UA) A 2006 01532

(51) Int. Cl. H01L 31/00

(52) U.S. Cl. 136/255

(57) ABSTRACT

The present invention is an integral thin-layer photovoltaic device, comprising a substrate with a coated layer of semiconductor materials, for example amorphous silicon of i-type conductivity, and made up of alternating areas, having different type of conductivity, different amounts of doping and/or band gap width, transparent and clear coatings on the front side, and electrical contacts. The alternating areas are formed in the initial film of semiconductor material as counter-comb, interleaved structures in the horizontal plane, and heterostructural areas are manufactured with variable ratios of crystal, micro-crystal, nano-crystalline and amorphous phases. The present invention is distinguished over prior art by several characteristics and advantages including a decreased number of process operations in its fabrication or manufacture, reduced consumption of semi-conductor material, simplified fabrication process, increased efficiency of solar energy conversion into electrical energy, and increased reliability.

### CROSS-REFERENCE TO RELATED APPLICATIONS

None

### FEDERALLY SPONSORED RESEARCH

None

### SEQUENCE LISTING NONE

Reference Documents Ukrainian Patent Application # a 2006 01532 PCT Application PCT/US2006/00002

### FIELD OF THE INVENTION

The present invention relates to microelectronics and specifically to a design and process for making inexpensive and highly efficient devices for conversion of light energy to electrical energy using semiconductors materials such as amorphous and nano-crystalline silicon and silicon alloys and other semiconductor materials.

### BACKGROUND OF THE INVENTION

Among the presently practiced means of producing photovoltaic (PV) devices are designs that include formation of semiconductor materials and structures in which vertical electron-hole transitions (EHT) occur. For example, the production method of a multi-transitional PV device described by Goradia C. and Goradia M.[1] involves the “stacking” of a number of mono-crystalline solar cells of an n⁺/n/p⁺ configuration, followed by formation of junctions in a furnace. Efficiency of solar cells of this design did not exceed 8%. PV efficiency is appreciably increased by a modification of the above described method through the addition of a horizontal p-n-transition, application of aluminum contacts and layers doped with aluminum [2].

A disadvantage of the above PV device designs and their associated production methods is that they are characterized by complication of the technological process and a large number of process operations or steps. Appreciable consumption of semiconductor materials is also a disadvantage of these methods. After cutting, polishing and chemical treatment, more than half of the silicon material in the blank used in mono-crystalline substrate production becomes industrial waste. Owing to its highly ordered crystalline structure, mono-crystalline silicon is relatively inefficient in absorbing sun light. This necessitates making the PV semiconductor layer relatively thick (more than 70 μm), thus requiring more material per unit area exposed to the incoming light. All of these disadvantages result in relatively high prime costs. Today the efficiency of the solar cells based on monocrystalline silicon with one vertical electron—hole transition reaches 16-20%. However it is possible due to high level intensity of use materials, power inputs that are kept at their manufacturing and, as consequence, the high cost of developed electric power.

With the goal to reduce the quantity of the silicon and as results to reduce the cost the thin film solar cells based on amorphous silicon are developed. PV devices with efficiencies of 13.5% have been made based on amorphous silicon alloy thin films. Examples of these, as described in [3-6], involve three transitions using 14 vertical layers. However, manufacture of these multi layer devices is greatly complicated, and degradation problems, including the Staebler-Wronksy degradation, are not effectively addressed. This degradation arises, in part, from the presence of interface layers between different materials as well as the doping of active semi conducting layers with hydrogen, which increases propensity to dissociate.

In one disclosed method of production [7], a thin film (0.15 to 5 μm) of amorphous semi-conductor material is deposited onto an insulating substrate. Then separate sections of this film are re-crystallized over their entire thickness by use of a laser in accordance with a predetermined topology. The topology used is that of alternate interleaving of amorphous (α-) and recrystallized (μc-) areas, forming a set of vertical EHTs. The resulting PV device becomes essentially a set of elemental photocells of i-α-/i-μc-type, which are formed into an integral PV module.

The possibility of additional doping by donor or acceptor-type elements on the film surface is also taught by this previous art. Doping is carried out simultaneously with re-crystallization under the treatment by laser. In such a case, the PV structure becomes a set of p-μc-/i-a-/n-μc-type elemental photocells. Such PV structure has higher efficiency as compared with the non-doped structure (i-a-/i-μc-) because of greater potential differences between the doped areas.

The above methods have a number of drawbacks and disadvantages. These include the homogeneity of amorphous silicon film doping over the entire depth of the material, contact between areas with different doping, different widths of forbidden zone (band gap) in the same plane, and non-planar electrical connection of separate PV cells in the module. This results in decreased conversion efficiency because of reduced light absorption, optical reflection, surface recombination of charge carriers, and the complexity of separate element connection in the PV module.

An objective of the present invention is the realization of an integral thin-layer PV device having maximum contact by three planes of a potential barrier surface (topology of horizontal counter combs), thus providing increased conversion efficiency and decreasing the number of process operations in fabrication or manufacture. In addition, such a design allows a decrease in the consumption of semiconductor materials, simplification of the manufacturing process and increased reliability of the resulting PV device or module (PVM). The present invention secure switch to design and technologies that does not require a mono-crystalline substrate, and the creation of the EHT is integral and horizontal.

### SUMMARY OF THE INVENTION

The subject matter of the present invention is an integral, horizontal thin-layer photovoltaic device, or photovoltaic module (PVM). According to the present invention, the above named objectives and advantages are achieved by creating an integral thin-layer PV device comprising a substrate with an applied layer of semiconductor material, for example amorphous silicon of intrinsic (i-type) conductivity and alternating areas or domains, having different types of conductivity and created in the initial film of amorphous silicon as an counter combs structure in the horizontal direction (FIG. 1).

The alternating areas of domains are created with the varying ratios of crystalline and amorphous phase materials. The operating range of this ratio could be from 0.15 to 0.95. The alternating areas of domains are created with the varying level of the nano crystallinity and varying size of the nano cryslallits. Thus the various structural modification of the same semiconductor material becomes important. These structure modifications differ in terms of the width of the forbidden zone (band gap), optical absorption, spectral distribution of photosensivity, conductivity in dark mode and photoconductivity.

The conductivity of the alternating areas (See FIG. 1) is varied by type, the amount or value of doping, the width of the forbidden zone. An anti-reflective coating is disposed on the front face area and electrical contacts are created as appropriate, among the alternating areas, having different types of conductivity.

The areas of n-type and p-type conductivity have non-homogeneous doping in the vertical direction, with the maximum doping level in the area of electrical contact, and a minimal doping level on the front face area, within the range of the doping level for example 10²¹-10¹⁷ cm⁻³.

Using an opaque substrate, a transparent conducting layer is applied to the n-type and p-type conducting surfaces, and electrical contacts are formed on the ends of PV cells. The placement of these contacts depends on the selected topology of the interconnected tracks (see FIG. 1).

The PV device of the present invention is distinguished by a number of advantages and promising characteristics. As illustrated in FIG. 1, alternating or interleaved domains or areas are manufactured with various degrees of nano-crystalline structure and different sizes of nano-crystals. As produced in the initial film of amorphous silicon, these alternating areas have different types of conductivity due to variations in doping values, or width of the forbidden zone (heterostructure) or both. The resulting interleaved or interlocked comb-like structures heterostructure regions in the horizontal direction are produced with variable ratios of nanocrystalline and amorphous phases. In manufacture, the design of the present invention requires fewer process steps, consumes less semiconductor material, and results in a PV with higher conversion efficiency and greater reliability than in the prior art as described above.

### BRIEF DESCRIPTION OF THE DRAWINGS

Details of the construction and practice of the present invention are further illustrated in the drawings below, and by their associated legends and descriptions.

FIG. 1 shows the overall design of the integral thin-layer photovoltaic module (PVM) with the various components designated as follows: 101 are recrystallized areas; 102 are amorphous areas; 103 designates the electrical contacts; and 104 is the base material-substrate.

### DETAILED DESCRIPTION OF THE INVENTION AND PREFERRED EMBODIMENTS

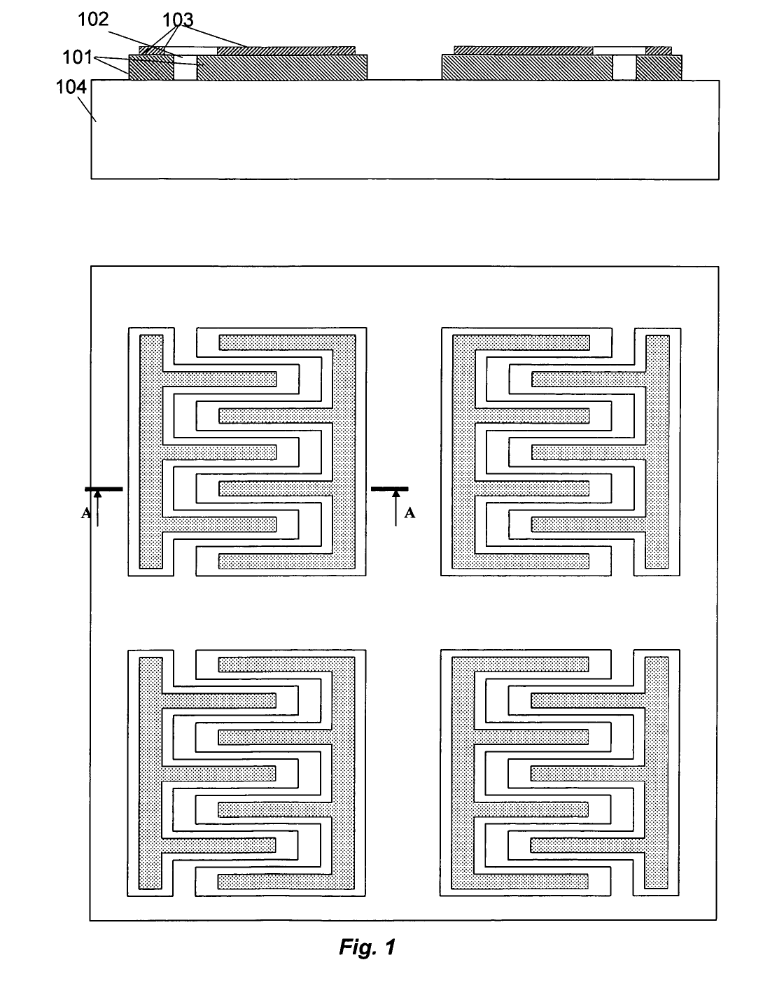

According to the present invention, PVM devices as depicted in FIG. 1 are fabricated as follows. A thin amorphous film of semiconductor material (102), of hydrogenated amorphous silicon (α-Si:H) or an alloy of amorphous silicon with yttrium, for example, is applied on a non-conducting insulating substrate (104). The substrate with the deposited film is placed in an suitable apparatus for treatment by a laser or other suitable spot-heating device.

The duration, rate and temperature of film material heating at points determined by the required topology (through masks, for example) are define by the operating parameters of the heating means. In the case of a laser, these parameters are wavelength, flux density (intensity), beam diameter and cross-section, as well as the overall exposure time. For pulsed laser operation, repetition rate and duration (duty cycle) are parameters that can be controlled to obtain the desired outcome. Re-crystallization extends through the entire thickness of the film. Laser parameters are regulated and re-crystallization of a defined section of the amorphous film is carried out such that a defined proportion of the material is nano-crystalline, this proportion being between 15% and 95% by volume.

If the volume of the percent of the film occupied by nano-crystals is less than 15% the increased mobility of the charge carriers does not occur. As the results the photosensivity and efficiency of the device is decreased. If the volume percent of the film occupied by nano-crystal is more than 95% mechanical stresses increase the and stability of the system decreases

Thus, the definite amorphous sections of film are transformed into the sections with the predetermined content of nano-crystals φ_{κp} and profile of nano-crystal distribution (crystallinity profile).

The presence of nano-crystals in the in amorphous material changes the width of the band gap E_{g} (for example, α-Si:H has E_{g}˜1.8 eV, whereas μc-Si:H has E_{g}˜1.55 eV). In a heterophase film between the amorphous (102) and the re-crystallized (101) areas, heterogeneous EHT appear, as would be the case between materials with different widths of the band gap E_{g}. The predetermined topology provides the relative alternation of the amorphous and nano-crystalline sections or domains. These form a set of electrically connected horizontal EHT. Based on predetermined electrical circuitry, these domains, in turn, form the integral thin-layer PVM. In addition to silicon alone, silicon alloys such aa α-Si:Ge:H, α-Si:C:H, and other semi-conducting materials can be used as a film material. These latter materials also have a high light absorption coefficient α in the amorphous state.

If glass or lavsan is used as a structural substrate, overheating of the base does not occur because these dielectric materials absorb far less light within the wave length range of laser beam (λ=0.3-10.0 μm). When strongly absorbing or highly conductive material, such as stainless steel is used as a structural substrate, then a several micron thick layer of dielectric between such material and the film of semiconductor material would be required. In the case of a flexible substrate material such as lavsan, or stainless steel foil, the PVM would also acquire flexibility. Such flexibility is provided by the present invention and becomes an additional advantage thereof.

Instead of a laser, an electron beam or ion beam may be used for heat treatment. However, to date, these heating means appear to be significantly inferior to the laser, both in terms of cost and technical outcome. Generation of a sufficiently narrow laser beam is readily accomplished. It is also possible to employ several laser beams simultaneously with each directed over a specific area on the target film. An approach consisting of sharp focus and scanning of the laser beam is preferred. With multiple laser beams, it is possible for them to work independently in different domains of the film and also to work in concert, having intersections within the plane of the film to take advantage of beam interference effects.

An initial semiconductor film can be applied by a number of techniques including plasma chemical deposition, magnetron sputtering, electrone or ion beam vapour deposition, ink technology and other. In the present invention, semiconductor film thickness ranges from 0.15 μm up to 2.0 μm The lower bound is determined by the fact that any semi-conductor film with a thickness less than 0.15 μm will not absorb more than 75% of incoming light energy over the wavelength range of interest for the PVM (λ=0.3-10.0 μm). The upper bound is determined by the technical difficulty of uniformly heating and qualitatively re-crystallizing films with a thickness of more than 2.0 μm with a laser or other spot heating means. Absorption of visible wavelength light is more than an order of magnitude better with amorphous and nano-crystalline silicon than mono-crystalline silicon.

Therefore, for optimal light absorption performance, the thickness of the base film should be in the range of approximately 0.7 to approximately 1.0 μm.

If the alloying elements of donor or acceptor type are deposited on the surface of the amorphous or nano-crystalline film of the semiconductor that is to be re-crystallized prior to laser or other type of treatment, then alloying will occur when the laser beam is applied, resulting in formation donor and acceptor centers. The initial film of the semiconductor material, under the action of the recrystallization, changes the ratio of amorphous and crystal phases. This allows control of the sizes of nanocrystalline inclusions. As a result it is possible to manage the important properties of the semiconductor materials.

This method allows efficient doping of the film in larger quantities and a broader range of chemical elements than the traditional doping methods for semiconductor materials. This approach also allows control of the doping profile in the corresponding layer in the vertical direction with greater concentrations near contacts, and the smaller concentrations near the illuminated surface. For example, by laser doping, Al, Ga, In, P, As or Sb can be introduced into α-Si:H at a rate that is from approximately 10 to 100 times greater than can be achieved by diffusion alloying.

In the case wherein a transparent substrate is used to make the PVM, the fabrication process proceeds as follows:
Formation of the main layer of semiconductor material (comprised of amorphous silicon, for example),
Application of the alloying elements thorough a mask to form the counter—combs or interleaved structure followed by removal of the masks from the surface. This process step can also be accomplished without masks over the entire film surface
Laser or other treatment is then carried out while changing the annealing time interval as required.
Electrical contacts are formed on the ends of the module elements depending on the selected interconnecting path topology

In this way it is possible to transfer to n⁺-μc-Si:H/i-α-Si:H/p⁺-μc-Si:H structures, or other structure types, by control of the annealing profile in the vertical direction.

In the case wherein an opaque base is used to make the PVM, the fabrication process proceeds as follows:
Formation of the main layer of semiconductor material (comprised of amorphous silicon, for example).
Application of the alloying elements thorough a mask to form the counter—combs or interleaved structure, followed by removal of the masks from the surface. This process step can also be accomplished without masks over the entire film surface
Laser or other treatment is then carried out while changing annealing time interval as required
Transparent conducting layer is applied to the n- and p-type conductivity regions,
Electrical contacts are formed on the ends of the module elements depending on the selected interconnecting path topology.

This allows a significant expansion of the PVM active area, and results in increased energy-conversion efficiency.

In the prior art the highly doped areas are clarified because in this area a significant portion of the charge carriers are being lost through recombination. This is especially true for short wavelength light.

PVM designed according to the present invention do not have this disadvantage, since the interface between elemental areas is formed by structural phase transformation. Light is simultaneously absorbed along the entire surface plane of the integrated PVM. As a result, there is no light loss on the highly-doped areas and the problems of surface and volume recombination, as well as degradation caused by the losses at the boundaries of different materials are eliminated.

In the present invention, there are fewer process steps in fabrication, and the process steps are less complex than in the prior art. This is especially the case at the stage of fabricating the initial film of the semiconductor on the substrate, where instead of intricate production processes for mono-crystalline oriented layer on the substrate, there is the comparatively simple application of a thin amorphous or nano-crystalline film to an inexpensive non-conducting substrate. At the stage of forming the working structure, there is simultaneous creation of all areas of the PVM. Thus, the multi-step and non-integral production process taught by prior art is replaced by the simple scheme of:
initial film application (1),
re-crystallization with
   predetermined ratio of the structured phases in the horizontal direction (2) and
   doping profile in the vertical direction (3)
with electrical contact formation.

The present invention provides a PVM that has less intrinsic cost and less weight per watt of power generated as compared to the prior art. Energy consumption by the equipment (for example laser, electron beam or ion beam used in fabrication for re-crystallization) does not constitute a significant cost factor since the film that is treated is thin and requires little heat for re-crystallization.

An important advantage of the present invention is the capability to vary the initial voltage and current of the PV device or PVM over very wide ranges by selection of equivalent circuit electrical connections between cells, and among cells, either in parallel or series connection, or combinations thereof, to obtain the required output voltage and current parameters.

PV devices designed according to the present invention have a wide range of applications, all the way from aerospace power sources to household and small personal electronic devices. Fields of application for the present invention include alternative energy, independent power sources for electronic equipment and instrumentation, remote sensors, communications equipment and biosensors.

### EXAMPLES

### Preferred Embodiments

Described below are examples illustrating the use and application of the present invention. These application examples and results are for illustration purposes only, and in no way limit the intended applications of the invention.

### Example 1

An amorphous film of hydrogenised silicon of i-type conductivity is applied to a glass substrate. A laser beam with a wave length of λ=0.365 nm and specific power of 20 mW/cm², 1 mW/cm² and 120 mW/cm² in pulse mode, for each pulse duration of 10 ns, is directed to the film surface. The laser beam is scanned over the surface in 2 mm steps. A structure consisting of the n-sub-structures composed of the alternating areas of nano-crystalline and amorphous and micro-crystalline silicon (e.g., n=10) is formed. On the ends of such heterojunction structures, the electrical contacts are formed by deposition of a conducting material such as aluminum.

### Example 2

An amorphous silicon film having intrinsic (i-type) conductivity is doped with yttrium (5 weight %) and applied to a glass substrate. A laser beam with a wave length of λ=0.365 nm and specific power 20 mW/cm², 1 mW/cm² and 120 mW/cm² is directed to the film surface. The duration of each pulse is 10 ns. The laser beam is scanned over the surface with a 2 mm—step. In this case a structure consisting of n-sub-structures made up of the alternating areas of nano-crystalline, amorphous and micro-crystalline silicon (e.g., n=10) is formed. On the ends of such heterojunction structures, electrical contacts are formed by deposition of a conducting material such as aluminum.

### Example 3

An amorphous silicon film having intrinsic (i-type)-conductivity is doped with yttrium (20 weight %) and applied to a glass substrate. A laser beam with the wave length λ=0.365 nm and specific power 20 mW/cm², 1 mW/cm² and 120 mW/cm² is directed at the film surface. The duration of each pulse is 10 ns. The laser beam is scanned over the surface in 2 mm increments.

In this case a structure consisting of n-sub-structures composed of alternating areas of nano-crystalline, amorphous and micro-crystalline silicon (e.g., n=10) is formed. On the ends of such heterojunction structures, electrical contacts are formed by deposition of a conducting material such as aluminum.

### Example 4

An amorphous silicon film of intrinsic (i-type) conductivity, doped by yttrium (30 weight %), is applied to a glass substrate. A laser beam with the wave length λ=0.365 nm and specific power 20 mW/cm², 1 mW/cm² and 120 mW/cm² is directed to the film surface. The duration of each pulse is 10 ns. The laser beam is scanned over the surface in 2 mm steps or increments. A structure consisting of n-sub-structures composed of alternating areas or domains of nano-crystalline, amorphous and micro-crystalline silicon (e.g., n=10) is formed. On the ends of such heterojunction structures, electrical contacts are formed by deposition of a conducting material such as aluminum.

### Example 5

An amorphous film of a silicon alloy having i-type-conductivity composed of Si (80%) and Ge(20%) is applied to a glass substrate. A laser beam with a wavelength of λ=0.365 nm and specific power of 20 mW/cm², 1 mW/cm² and 120 mW/cm² is directed at the film surface. The duration of each pulse is 10 ns. The laser beam is scanned over the surface in 2 mm increments. A structure consisting of n-sub-structures composed of alternating areas of nano-crystalline, amorphous, and micro-crystalline silicon (e.g., n=10) is formed. On the ends of such heterojunction structures, the electrical contacts are formed by deposition of a conducting material such as aluminum.

### Example 6

An amorphous silicon film of i-type conductivity is applied on a substrate of polymer such as polyimide, and doped with yttrium (5 weight %). A laser beam with a wavelength of λ=0.365 nm and specific power of 20 mW/cm², 1 mW/cm² and 120 mW/cm² in a pulsed mode, with pulse duration of 10 ns, is directed at the film surface. The laser beam is scanned over the surface in 2 mm increments. A structure consisting of n-sub-structures composed of alternating areas or domains of nano-crystalline, amorphous and micro-crystalline silicon (e.g., n=10) is formed. On the ends of the heterojunction structures thus formed, electrical contacts are formed by deposition of a conducting material such as aluminum.

### Example 7

An amorphous silicon film of i-type conductivity is applied on a glass substrate. The beam of an ultraviolet laser with the specific power 10 mW/cm², 30 mW/cm², 1 mW/cm², 30 mW/cm², and 120 mW/cm² in a pulse mode, (10 ns—duration of each pulse) is directed at the film surface. The laser beam is scanned over the surface in 2 mm increments. A structure is formed consisting of n-substructures composed of alternating areas or domains of silicon with different sizes of crystallites including nanocrystalline silicon (3-4 nm), nanocrystalline silicon (7-8 nm), amorphous silicon, nanocrystalline silicon (3-4 nm), and micro-crystalline. Electrical contacts are formed on the ends of the heterojunction structures by deposition of a conducting material such as aluminum.

### Example 8

An amorphous silicon film of i-type-conductivity and doped by yttrium (5 weight %), is applied to a glass substrate. An ultraviolet laser beam with pecific power of 10 mW/cm², 30 mW/cm², 1 mW/cm², 30 mW/cm² and 120 mW/cm² is directed at the film surface. The duration of each pulse is 10 ns. The laser beam is scanned over the surface in 2 mm increments. A structure is formed consisting of n-substructures composed of alternating areas or domains of silicon with different sizes of crystallites including nanocrystalline silicon (3-4 nm), nanocrystalline silicon (7-8 nm), amorphous silicon, nanocrystalline silicon (7-8) and micro-crystalline silicon. Electrical contacts are formed on the ends of the heterojunction structures by deposition of a conducting material such as aluminum.

### Example 9

An amorphous film of the alloy Si(80%)-Ge(20%) of i-type conductivity is applied on a glass substrate. The beam of an ultraviolet laser with specific power of 10 mW/cm², 30 mW/cm², 1 mW/cm², 30 mW/cm², and 120 mW/cm² in a pulse mode, (10 ns-duration of each pulse) is directed at the film surface.

The laser beam is scanned over the surface in 2 mm increments. A structure consisting of n-substructures composed of alternating areas of silicon with different sizes of crystals, including nanocrystalline silicon (3-4 nm), nanocrystalline silicon (7-8 nm), amorphous silicon, nanocrystalline silicon (7-8 nm) and micro-crystallin is formed. Electrical contacts are formed on the ends of the heterojunction structures by deposition of a conducting material such as aluminum.

### Example 10

The amorphous film of hydrogenised silicon of i-type conductivity is applied to a glass substrate. By the method of vacuum resistive spraying, through a masks having a predetermined topology, aluminum and antimony films, which are acceptor and donor admixtures, respectively, are applied to the surface of amorphous silicon film. Then a laser beam with a wavelength of λ=0.365 nm and specific power 20 mW/cm², 1 mW/cm² and 120 mW/cm² in a pulsed mode, with each pulse having a duration of 10 ns, is directed to a film surface. The laser beam is scanned over the surface in 2 mm increments. A structure consisting of the n-sub-structures composed of the alternating areas of nano-crystalline, amorphous and micro-crystalline silicon (e.g., n=10) is formed. Electrical contacts are formed on the ends of the heterojunction structures by deposition of a conducting material such as aluminum.

### Example 11

An amorphous film of hydrogenated silicon (α Si:H) of i-type conductivity, and doped by yttrium (5 weight %), is applied to a glass substrate. By the method of vacuum resistive spraying, through masks of predetermined topology, aluminum and antimony films, which are acceptor and donor admixtures, respectively, are applied on the surface of the amorphous silicon film. Then a laser beam with a wavelength of λ=0.365 nm and specific power of 20 mW/cm², 1 mW/cm² and 120 mW/cm² in a pulsed mode, with pulse duration of 10 ns, is directed at the film surface. The laser beam is scanned over a surface in 2 mm increments.

A structure consisting of n-sub-structures composed of alternating areas of nano-crystalline, amorphous and micro-crystalline silicon (e.g., n=10) is formed. Electrical contacts are formed on the ends of the heterojunction structures by deposition of a conducting material such as aluminum.

### Example 12

An amorphous film of hydrogenated silicon of i-type conductivity is applied to a glass substrate. By the method of vacuum resistive spraying, through masks with predetermined topology, aluminum and antimony films, which are acceptor and donor admixtures, respectively, are applied on the surface of the amorphous silicon film. Thereafter an ultraviolet laser beam with specific power of 10 mW/cm², 30 mW/cm², 1 mW/cm², 30 mW/cm², 120 mW/cm² in a pulsed mode, with each pulse duration of 10 ns, is directed at the film surface. The laser beam is scanned over a surface in 2 mm increments. A structure is formed consisting of n-sub-structures composed of alternating areas of nano-crystalline, amorphous silicon and micro-crystalline silicon (e.g., n=10). Electrical contacts are formed on the ends of the heterojunction structures by deposition of a conducting material such as aluminum.

Table 1 below shows the parameters of the PV modules that were fabricated as described in the various Examples provided. The parameters in Table 1 are for PVM wherein 10 structures of photoelectric converters are series-connected.

TABLE 1
Parameters of integral photovoltaic modules as fabricated in the
above examples.

| | | | | | Number of |
|---|---|---|---|---|---|
| | | | | | operations |
| | | | | | required to |
| | | Short circuit | | | manufacture |
| | Open | current | | | the integrated |
| Example | circuit | density, | Fill- | Efficiency | photovoltaic |
| number | voltage, V | (mA/cm²⁾ | factor | (%) | module |
| 1 | 8.1 | 16.1 | 0.68 | 8.86 | 4 |
| 2 | 8.5 | 18.2 | 0.67 | 10.4 | 4 |
| 3 | 8.15 | 16.9 | 0.66 | 9.0 | 4 |
| 4 | 8.3 | 17.4 | 0.66 | 9.5 | 4 |
| 5 | 8.2 | 17.8 | 0.67 | 9.8 | 4 |
| 6 | 7.9 | 16.0 | 0.65 | 8.2 | 4 |
| 7 | 8.7 | 18.0 | 0.68 | 10.6 | 4 |
| 8 | 8.9 | 18.7 | 0.69 | 11.5 | 4 |
| 9 | 8.6 | 18.1 | 0.68 | 10.6 | 4 |
| 10 | 9.1 | 19.3 | 0.69 | 12.1 | 6 |
| 11 | 9.3 | 20.5 | 0.69 | 13.1 | 6 |
| 12 | 9.5 | 21.4 | 0.7 | 14.2 | 6 |

### CLOSURE

While various embodiments of the present invention have been shown and described, it will be apparent to those skilled in the art that many changes and modifications may be made without departing from the invention in its broader aspects.

We claim:

1. An integral thin-layer photovoltaic device comprising a substrate with an applied layer of semiconductor material that make up alternating areas or domains, which are created in the initial film of semiconductor material as an counter-comb structure in the horizontal direction, wherein the alternating areas or domains have n and p types of conductivity, different amounts or values of doping, and wherein the width of the forbidden zones (band gaps) and are created with varying levels of nano crystallinity, varying sizes of the nano crystallites, and a variable ratio of the crystalline and amorphous phase materials in the range of 0.15 to 0.95 (15 to 95 volume %).

2. An integral thin-layer photovoltaic device as in claim 1 wherein the regions of n- and p-type conductivity have non-uniform alloying in the vertical direction with the maximum in the region of electrical contacts, and minimal on front-face area, for example, within the range of doping from 10²⁰ to 10¹⁷ cm⁻¹.

3. An integral thin-layer photovoltaic device as in claim 1 wherein the initial film of the semiconductor material that is applied of the substrate is an amorphous silicon of α-Si:H intrinsic (i-type) conductivity.

4. An integral thin-layer photovoltaic device as in claim 1 wherein the semiconductor material that is applied of the substrate is nanocrystalline silicon.

5. An integral thin-layer photovoltaic device as in claim 3 wherein the initial film of the amorphous silicon film having intrinsic (i-type) conductivity is doped with yttrium.

6. An integral thin-layer photovoltaic device as in claim 5 wherein the quantity of the yttrium is from 5% up to 30%.

7. An integral thin-layer photovoltaic device as in claim 3 wherein the initial amorphous film of a silicon alloy composed of Si and rare-earth elements.

8. An integral thin-layer photovoltaic device as in claim 7 wherein the amorphous film is of a silicon alloy composed of Si consisting of 80% Si and 20% Ge i-type-conductivity.

9. An integral thin-layer photovoltaic device as in claim 3 wherein aluminum and antimony films, which are acceptor and donor admixtures, respectively, are applied on the surface of the initial amorphous silicon film before creation of the said alternating domains or areas.

10. An integral thin-layer photovoltaic device as in claim 1 wherein the structure of the alternating areas or domains consisting of the n-sub-structures composed of alternating areas of nano-crystalline, amorphous and micro-crystalline silicon (e.g., n=10) is formed.

11. An integral thin-layer photovoltaic device as in claim 9 wherein the structure consisting of n-substructures composed of alternating areas of silicon with different sizes of crystals, including nanocrystalline silicon (3-4 nm), nanocrystalline silicon (7-8 nm), amorphous silicon, nanocrystalline silicon (7-8 nm) and micro-crystallin is formed.

12. An integral thin-layer photovoltaic device as in claim 1 wherein the alternating areas or domains are created in the initial film of semiconductor material as a counter combs structure in the horizontal direction by laser beam treatment.

13. An integral thin-layer photovoltaic device as in claim 10 wherein a laser beam with a wave length of λ=0.365 nm and specific power from 1 mW/cm² up to 120 mW/cm² in a pulsed mode, with pulse duration of 10 ns, is directed at a film surface and is scanned over a surface in 2 mm increments.

14. An integral thin-layer photovoltaic device as in claim 1, wherein during application of opaque substrate, a transparent layer is deposited on the front side of n- and p-type regions, and electrical contacts are formed on the ends of the photo-modulus depending on the selected parallel-series connection configuration.

15. Integral thin-layer photovoltaic device as in claim 1 characterized in that the interchangeable regions are produced with the different degree of nanocrystallinity.

16. Integral thin-layer photovoltaic device at in claim 1 characterized in that the interchangeable regions are produced with the different size of nanocrystallites.
